(19) United States
(12) Patent Application Publication
(10) Pub. No.: US 2022/0281705 A1
(43) Pub. Date: Sep. 8, 2022

(54) LIGHT EMITTING LOAD TRANSDUCERS

(71) Applicant: HEWLETT-PACKARD DEVELOPMENT COMPANY, L.P., Spring, TX (US)

(72) Inventors: Agusti Garcia Pujol, Sant Cugat del Valles (ES); Oscar Lopez Lopez, Sant Cugat del Valles (ES); Pedro Luis Las Heras Sanz, Sant Cugat del Valles (ES)

(21) Appl. No.: 17/753,569

(22) PCT Filed: Sep. 23, 2019
(86) PCT No.: PCT/US2019/052439

§ 371 Date: Mar. 8, 2022

(51) Int. Cl. B65H 23/02; B65H 23/188

(52) U.S. Cl. CPC B65H 23/0216; B65H 23/188; B65H 2553/26; B65H 2801/03; B65H 2404/152

(57) ABSTRACT

An apparatus is disclosed. The apparatus comprises a transducer to transform a load in the housing to an electric current, upon receipt of a load exceeding a load threshold. The apparatus further comprises a light source coupled to the transducer to emit light upon receiving the electric current.

### BACKGROUND

Some printing systems generate printed images by propelling printing fluid through nozzles onto printing media locations associated with virtual pixels. The printing fluid drops may comprise pigments or dyes disposed in a liquid vehicle. The media may move with respect the inkjet printer with the aid of a media conveying system.

### BRIEF DESCRIPTION OF THE DRAWINGS

The present application may be more fully appreciated in connection with the following detailed description of non-limiting examples taken in conjunction with the accompanying drawings, in which like reference characters refer to like parts throughout and in which:

FIG. 1 is a schematic diagram showing an example of an apparatus to emit light upon receiving a load exceeding a load threshold.

FIG. 2 is a schematic diagram showing an example of another apparatus to emit light upon receiving a load exceeding a load threshold.

FIG. 3 is a schematic diagram showing an example of a media conveying system to emit light upon receiving a load exceeding a load threshold.

FIG. 4 is a schematic diagram showing an example of a system, comprising a wheel, to emit light upon receiving a load exceeding a load threshold.

### DETAILED DESCRIPTION

Some examples of the following description are directed to various examples related to printing systems, apparatuses and processes to generate high quality printed objects. Throughout the present disclosure, the terms “a” and “an” are intended to denote at least one of a particular element. In addition, as used herein, the term “includes” means includes but not limited to, the term “including” means including but not limited to. The term “based on” means based at least in part on.

For simplicity, it is to be understood that in the present disclosure, elements with the same reference numerals in different figures may be structurally the same and/or may perform the same functionality.

Some printers, such as Large Format Printers, comprise media conveying systems to transfer an amount of media from one place to another with respect to a media advance direction (referred hereinafter as Y direction). In some examples, the media conveying systems may transfer media rolled in a media input roller to a media output roller located at the opposite side of the printing zone. In other examples, however, the amount of media may be transferred in a linear way through the printing zone.

In any case, differential tensions caused by the conveying system onto the media along the media width (referred hereinafter as X direction) may cause the media skew or deviate from the intended media path direction along the width of the media (e.g., at both ends of the width of the media) and, thereby compromise the image quality of the print job. In some examples, the conveying system may be to convey the media advance in a direction substantially orthogonal to the media width direction.

The root cause of these differential tensions may be hard to determine and to detect. However, a user being able to visually determine the presence of differential tensions between the conveying system and the media, may enable the user to correct the deficiency and increase the image quality of the print job as the print job is being printed.

In the examples herein, the term media may comprise any media suitable to be printed thereon. Some examples of media may include paper, textile, cardboard, wood, tin, and/or metal.

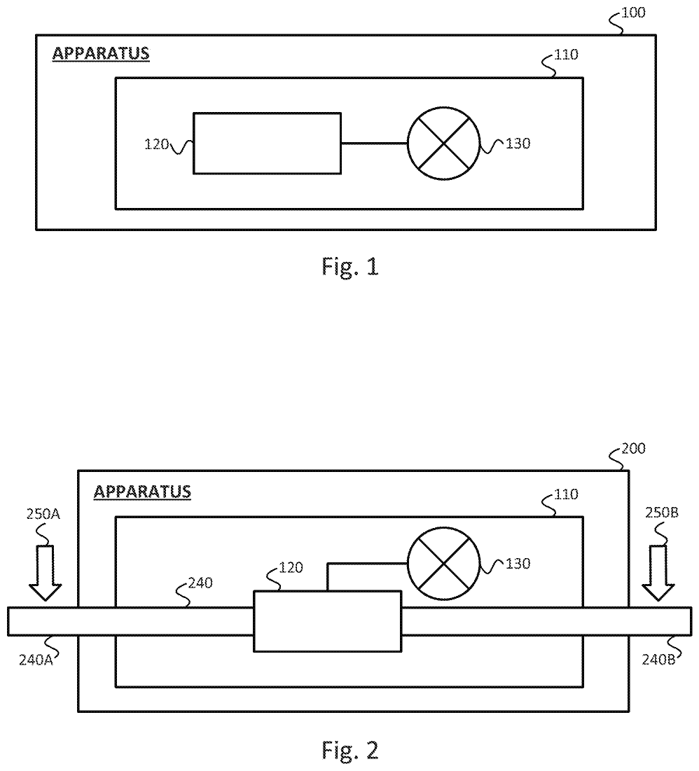

Referring now to the drawings, FIG. 1 is a schematic diagram showing an example of an apparatus 100 to emit light upon receiving a load exceeding a load threshold. The apparatus 100 comprises a housing 110.

The housing 110 comprises at least a wall that enables the transfer of light therethrough. In an example, the housing 110 is made of transparent or translucent material thereby enabling the transfer of light in its entirety. In other examples, however, a section of the housing 110 is made of a transparent or translucent material that enables the transfer of light through the section. The housing 110 may be built from a plurality of materials. Some examples of materials in which the housing 110 may be built comprise Polyamide, Acrylonitrile Butadiene Styrene (ABS), Polyurethane, Polycarbonate, Methacrylate, glass or the like. Some examples of materials in which the housing 110 may be built have been disclosed. However, any suitable material which enables the transfer of light therethrough may be used without departing from the scope of the present disclosure.

The housing 110 encloses a transducer 120 therein. A transducer 120 may be understood as any suitable device that converts energy from one form to another. In the examples herein, the transducer 120 may be an electrical transducer to transform a load in the housing to an electric current upon receipt of a load exceeding a load threshold. In the present disclosure a load may include any external mechanical force, pressure, acceleration, temperature, strain, deflection or resistance on the housing 110. In some examples, a load exerted in the vicinity of an edge of the housing 110 may cause the housing 110 to deflect, bend and/or twist. In these examples, the transducer 120 may transform either the load or the deflection into an electric current.

In some of the examples herein, the transducer 120 may trigger an electric current based on a predetermined load. The predetermined load may be referred to hereinafter as a load threshold. Therefore, in the ongoing examples, the transducer 120 may not generate any electrical current if the housing 110 is subject to a load lower the load threshold. Likewise, the transducer may generate an electrical current if the housing is subject to a load higher than the load threshold.

As mentioned above, the transducer 120 may include any device that converts a load to an electric current. For example, the transducer 120 may be a piezoelectric element. A piezoelectric element is a device that converts a load to an electric current through the piezoelectric effect which comprises accumulating an electric charge in certain solid materials in response to an applied load.

The apparatus 100 further comprises a light source 130 coupled to the transducer 120 to emit light upon receiving the electric current from the transducer 120. The emitted light may travel through the wall of the housing 110 to be visible to the user. Upon acknowledging the emitted light, the user may determine that the housing 110 is subject to an amount of load that exceeds the predefined load threshold.

In the examples herein, the light source 130 may be any suitable device to emit light upon receiving an electric current. For example, the light source 130 may be a Light-Emitting Diode (LED). Other examples of light source 130 may comprise an incandescent light bulb, an infrared lamp, a fluorescent tube, a halogen lamp, a discharge lamp, or the like.

In another example of the present disclosure, the transducer 120 may be a load cell connected to a circuitry element (not shown). In this example, the load cell may measure an amount of load on the load cell. The circuitry element may detect that the load cell measurement from the load cell exceeds a previously encoded load threshold. The circuitry element may further switch the light source 130 to emit light upon detecting that the load cell measurement exceeds the load threshold.

FIG. 2 is a schematic diagram showing an example of another apparatus 200 to emit light upon receiving a load exceeding a load threshold. Parts of the apparatus 200 may be the same as or similar to parts of the apparatus 100 from FIG. 1. The apparatus 200 comprises the housing 110, the transducer 120 and the light source 130.

Some of the examples herein refer to a shaft 240. It is to be understood that in some examples, the shaft 240 may be suitable to rotate along the length of the shaft 240 (i.e., length of the shaft 240 as rotation axis). In other examples, however, the shaft 240 may not rotate.

The housing 110 of the apparatus 200 encloses, at least partially, a shaft 240. In some examples, the housing 110 fully encloses the shaft 240. In other examples, however, the housing 110 partly encloses the shaft 240 (i.e., illustrated example). In the illustrated example, the shaft 240 is subject to a load 250A-B. In the example, a first end of the shaft 240A is subject to a first part of the load 250A and a second end of the shaft 240B is subject to a second part of the load 250B. A load configuration example has been disclosed, however any other suitable load configuration may be used without departing from the scope of the present disclosure, for example, by applying an external mechanical force, a pressure, an acceleration, raising/lowering temperature, a strain, any other deflection or a resistance on the shaft 240.

The transducer 120 may be co-axially coupled to the housing 110 through the shaft 240, to transfer a load effect (e.g., load 240A-B) in the shaft to an electric current, if the effect of the load exceeds the load threshold. In an example, the illustrated load configuration may cause the shaft 240 to deflect up to a deflection threshold (i.e., load threshold in which the load causes a deflection in the shaft 240) in which the transducer 120 may trigger an electric current to cause the light source 130 to emit light. Other load configuration examples may cause the shaft 240 to compress, traction, heat, cool, bend, twist and/or the like, based on the corresponding type of load applied to the shaft 240.

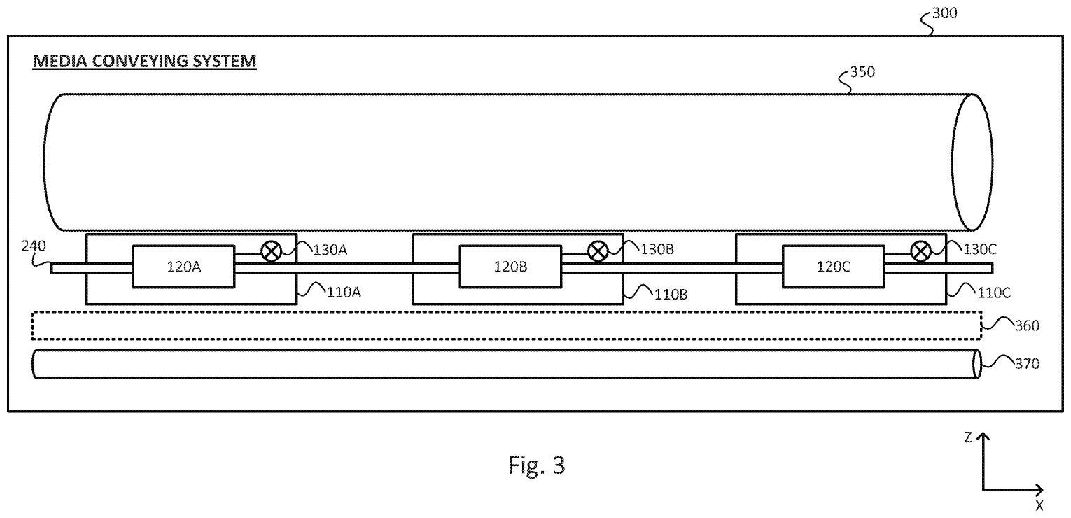

FIG. 3 is a schematic diagram showing an example of a media conveying system 300 to emit light upon receiving a load exceeding the load threshold. Parts of the media conveying system 300 may be the same as or similar to parts of the apparatus 100 and 200 from FIGS. 1 and 2 respectively. The media conveying system 300 disclosed herein may be suitable to be an integral part or a printing media device (e.g., Large Format Printer), a scanning media device (e.g., media scanner), or any device that is to convey media.

The media conveying system 300 is to transport (i.e., convey) media 360 through two opposite ends with respect to the media conveying system 300. The media 360 is illustrated in dotted lines to denote that it is an external element that interacts with the media conveying system 300, and thereby it is not an integral part of the media conveying system 300 as such.

As mentioned above, the media 360 may be any media suitable to be printed thereon. Some examples of media 360 may include paper, textile, cardboard, wood, tin, and/or metal. In some examples, the media 360 may be supplied to the media conveying system 300 as a plurality of sheets of media 360 and the media conveying system 300 may transport at least one sheet of media 360 from the plurality of sheets of media 360 through two opposite ends of the media conveying system 300. In other examples, however, the media 360 may be supplied to the media conveying system 300 as a continuous sheet of media rolled in a media input roller at a first end of the system 300, and the media conveying system 300 is to transport the media from the media input roller to a media output roller located at a second end of the system 300.

The media conveying system 300 comprises a media advancement roller 370 and a sensing roller 350. The media 360 is to be located between the media advancement roller 370 and the sensing roller 350. The media advancement roller 370 is to cause advancement of the media 360 located thereon by, for example, rotating and generating a friction between the media advancement roller 370 and the media 360 to cause the media 360 to advance in a controlled manner. The media advancement roller 370 may be coupled and controllable by a controller (not shown). In the illustrated example, the media 360 may be conveyed with respect to the direction coming in or coming out the drawing.

The sensing roller 350, also known as pressing roller, is a roller located at the opposite side the media 360 with respect to the media advancement roller 370. The sensing roller 350 is to create a pressure to the media 360 so that the media 360 does not move along the vertical axis (e.g., Z axis) as the media 360 is being conveyed by the media advancement roller 370. In other words, the sensing roller 350 is to inhibit the vertical movement of the media 360 as the media 360 is being conveyed through the media conveying system 300. The examples in which the vertical movement of the media 360 is not inhibited may lead to wrinkles, banding and/or other image quality defects. In some examples, the sensing roller 350 may not rotate, and thereby may press the media 360 in the vertical direction. In other examples, however, the sensing roller 350 may inhibit the vertical movement of the media 360 by rotating. In these examples, the sensing roller 350 may be coupled to a controller and the controller may control the rotation of the sensing roller 350.

In the examples herein, a controller may be any combinations of hardware and programming that may be implemented in a number of different ways. For example, the programming of modules may be processor-executable instructions stored on at least one non-transitory machine-readable storage medium and the hardware for modules may include at least one processor to execute those instructions. In some examples described herein, multiple modules may be collectively implemented by a combination of hardware and programming. In other examples, the functionalities of the controller may be, at least partially, implemented in the form of an electronic circuitry. The controller may be a distributed controller, a plurality of controllers, and the like.

The media conveying system 300 further comprises a plurality of housings 110A-110C, each of them comprising at least a wall that enables the transfer of light therethrough. In an example, a housing from the plurality of housings 110A-110C is a wheel. In another example, a housing from the plurality of housings 110A-110C is a roller. In yet another example, a housing from the plurality of housings 110A-110C is a sphere. Some examples of the shape of a housing have been disclosed, however it is to be understood that any shape suitable to perform the functionality disclosed herein may be used without departing from the scope of the present disclosure.

Each of the housings from the plurality of housings 110A-110C encloses a transducer therein (e.g., transducers 120A-120C respectively), and each transducer 120A-120C is respectively coupled to a light source 130A-130C. In some examples, each housing 110A-110C is attached (e.g., glued) to the sensing roller 350. However, in other examples (e.g., illustrated example), each of the housings 110A-110C and/or each of the transducers 130A-130C may be co-axially coupled to a shaft 240. In the illustrated example, the media conveying system 300 comprises three housings 110A-110C, transducers 120A-120C, and light emitters 130A-130C, however it is to be understood that any number of housings, transducers, and light emitters may be used without departing from the scope of the present disclosure, for example, one, five or ten housings, transducers, and light emitters.

As mentioned above, differential tensions of the conveying system 300 and the media 360 along the media width axis (e.g., X axis) may cause the media 360 to not advance in parallel at different parts of the width of the conveying system 300 and, thereby compromise the image quality of the print job. In the examples herein, the aforementioned tensions (e.g., load, pressure, force, compressing force, and the like) on the media 360 may be caused by, for example, the sensing roller 350. In other examples, the tensions may be caused by another element or by a combination of the sensing roller 350 and another element.

In the example, the sensing roller 350 may generate a load that causes a compressive force on the plurality of housings 110A-110C. The distribution of the load may not be evenly distributed across the plurality of housings 110A-110C, thereby leading to the media 360 not advancing in parallel at different parts of the width of the media conveying system 300.

Each of the plurality of housings 110A-110C may receive a corresponding distributed amount of force (e.g., load) thereon. Additionally, the load may cause the shaft 240 to deflect, bend and/or twist. Each of the transducers 120A-120C is to transform the corresponding distributed amount of force that each of the transducers 120A-120C are subject to, into a corresponding electric current. Each of the transducers 120A-120C may execute the aforementioned transformation if the corresponding amount of force that the transducers 120A-120C are subject to, exceeds a force threshold (e.g., load threshold). In some examples, the transducers 120A-120C may not be encodable and may trigger an electric current upon receiving at least an amount of force corresponding to a factory-designed amount of force of the transducers 120A-120C from the transducer manufacturer. In other examples, however, the transducers may be encodable to trigger the electric current upon receiving an amount of force of at least the force threshold.

In the example, as each of the transducers 120A-120C is respectively coupled to a light source 130A-130C, a transducer triggering an electric current may cause the respectively coupled light source to emit light. The emitted light may travel through the wall of the respective housing to be visible by a user. The user, in response to seeing the emitted light, notices not only that a part of the width of the media 360 is not advancing in parallel due to an excess of load, but also the width location in which the excess of load is happening. The user may correct the deficiency prior to printing the full print job with a deficient image quality.

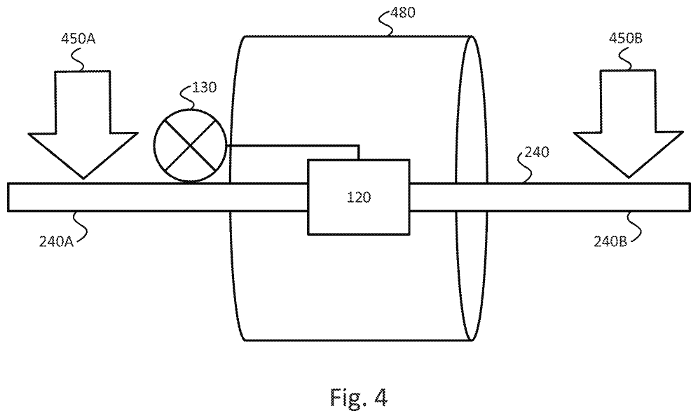

FIG. 4 is a schematic diagram showing an example of a system 400, comprising a wheel 480, to emit light upon receiving a load exceeding a load threshold. Parts of the system 300 may be the same as or similar to parts of the apparatus 100 and 200 from FIGS. 1 and 2 respectively. The system 300 comprises the shaft 240, the transducer 120, the light source 130.

The system 400 may be an integral part of a bigger structure or machine, such as a Large Format Printer, a 3D printer, or any other structure comprising at least a wheel. In some additional examples, the big structure or machine may perform a calibration operation of the wheel based on the load that the wheel is subject to. Acknowledging by visual inspection that the wheel is subject to an excessive load may has benefits in the calibration operation. In the examples herein, the aforementioned bigger structure or machine may be referred hereinafter as the external structure.

The system 400 comprises the wheel 480 coupled to the shaft 240. The wheel 480 may be any suitable wheel to perform its function based on the nature of the external structure. In some examples, the shaft 240 may be the rotation shaft of the wheel. In other examples, the shaft 240 may not be the rotation shaft of the wheel and thereby may not rotate in synchrony with the wheel 480. In yet other examples, the shaft 240 may be a static shaft.

The external structure may cause a load (not shown) to the shaft 240. In some examples, the load may be caused by the weight of at least a part of the external structure. The load may be distributed among a first end 240A of the shaft 240 and a second end 240B of the shaft 240. The first end 240A of the shaft 240 may receive a first load 450A and the second end 240B of the shaft 240 may receive a second load 450B. The load may be distributed into the first load 450A and the second load 450B. The values of the first load 450A and the second load 450B may depend at least on one of the geometry of the external structure, the geometry of the shaft, the material of the shaft, and the load to be distributed. The first load 450A at the first end 240A of the shaft 240 and the second load 450B at the second end 240B of the shaft 240 may cause the shaft 240 to deflect, bend and/or twist.

The transducer 120 may be co-axially coupled to the shaft 240, to transform a deflection in the shaft to an electric current, if the effect of the load exceeds a deflection threshold (e.g., load threshold). To set an example, the illustrated load configuration may cause the shaft 240 to deflect up to a deflection threshold (i.e., load threshold in which the load causes a deflection in the shaft 240) in which the transducer 120 may trigger an electric current to cause the light source 130 to emit light and alert the user that the wheel 480 may be subject to an excessive load from the external structure.

The above examples may be implemented by hardware, or software in combination with hardware. For example, the various methods, processes and functional modules described herein may be implemented by a physical processor (the term processor is to be implemented broadly to include CPU, SoC, processing module, ASIC, logic module, or programmable gate array, etc.). The processes, methods and functional modules may all be performed by a single processor or split between several processors; reference in this disclosure or the claims to a “processor” should thus be interpreted to mean “at least one processor”. The processes, method and functional modules are implemented as machine-readable instructions executable by at least one processor, hardware logic circuitry of the at least one processors, or a combination thereof.

As used herein, the terms “about” and “substantially” are used to provide flexibility to a numerical range endpoint by providing that a given value may be, for example, an additional 20% more or an additional 20% less than the endpoints of the range. The degree of flexibility of this term can be dictated by the particular variable and would be within the knowledge of those skilled in the art to determine based on experience and the associated description herein.

The drawings in the examples of the present disclosure are some examples. It should be noted that some units and functions of the procedure may be combined into one unit or further divided into multiple sub-units. What has been described and illustrated herein is an example of the disclosure along with some of its variations. The terms, descriptions and figures used herein are set forth by way of illustration. Many variations are possible within the scope of the disclosure, which is intended to be defined by the following claims and their equivalents.

There have been described example implementations with the following sets of features:

Feature set 1: An apparatus comprising:
a housing, wherein at least part of the housing comprises a wall that enables the transfer of light therethrough;
a transducer within the housing to transform a load in the housing to an electric current, upon receipt of a load exceeding a load threshold; and
a light source coupled to the transducer to emit light upon receiving the electric current.

Feature set 2: An apparatus with feature set 1, wherein the transducer is a piezoelectric element.

Feature set 3: An apparatus with any preceding feature set 1 or 2, wherein the housing encloses, at least partially, a shaft, being the transducer co-axially coupled to the housing to transform a load in the shaft to an electric current.

Feature set 4: An apparatus with any preceding feature set 1 to 3, wherein the transducer is a load cell, the apparatus further comprising a circuitry to: detect that a load cell measurement from the load cell exceeds the load threshold; and switch the light source to emit light upon detecting that the load cell measurement exceeds the load threshold.

Feature set 5: An apparatus with any preceding feature set 1 to 4, wherein the light source is a Light-Emitting Diode (LED).

Feature set 6: An apparatus with any preceding feature set 1 to 5, wherein the housing is made, at least in part, of at least one of Polyamide, Acrylonitrile Butadiene Styrene (ABS), Polyurethane, Polycarbonate, Methacrylate, or glass.

Feature set 7: A media conveying system comprising:
a media advancement roller to cause advancement of a media located between the media advancement roller and a sensing roller;
the sensing roller;
a housing that comprises a wall that enables the transfer of light therethrough;
a transducer within the housing to transform a force in the housing to an electric current, if the force exceeds a force threshold; and
a light source coupled to the transducer to emit light upon receiving the electric current.

Feature set 8: A media conveying system with feature set 7, wherein the force is a compressing force caused by a load, the load to be generated by the sensing roller.

Feature set 9: A media conveying system with any preceding feature set 7 to 8, wherein the system is a conveying system for a printing media device or a scanning media device.

Feature set 10: A media conveying system with any preceding feature set 7 to 9, wherein the transducer is a piezoelectric element

Feature set 11: A media conveying system with any preceding feature set 7 to 10, wherein the light source is a Light-Emitting Diode (LED).

Feature set 12: A media conveying system with any preceding feature set 7 to 11, wherein the housing is a wheel, a roller, or a sphere.

Feature set 13: A system comprising:
a wheel to be coupled to a shaft, the shaft to receive a first load at a first end and a second load at a second end that cause a deflection in the shaft;
a transducer co-axially coupled to the shaft to transform the deflection to an electric current, if the deflection exceeds a deflection threshold; and
a light source coupled to the transducer to emit light upon receiving the electric current

Feature set 14: A system with feature set 13, wherein the transducer is a piezoelectric element.

Feature set 15: A system with any preceding feature set 13 to 14, wherein the first load and the second load are caused by a weight of a machine.

What it is claimed is:

1. An apparatus comprising:
a housing, wherein at least part of the housing comprises a wall that enables the transfer of light therethrough;
a transducer within the housing to transform a load in the housing to an electric current, upon receipt of a load exceeding a load threshold; and
a light source coupled to the transducer to emit light upon receiving the electric current.

2. The apparatus of claim 1, wherein the transducer is a piezoelectric element.

3. The apparatus of claim 1, wherein the housing encloses, at least partially, a shaft, being the transducer co-axially coupled to the housing to transform a load in the shaft to an electric current.

4. The apparatus of claim 1, wherein the transducer is a load cell, the apparatus further comprising a circuitry to:
detect that a load cell measurement from the load cell exceeds the load threshold; and
switch the light source to emit light upon detecting that the load cell measurement exceeds the load threshold.

5. The apparatus of claim 1, wherein the light source is a Light-Emitting Diode (LED).

6. The apparatus of claim 1, wherein the housing is made, at least in part, of at least one of Polyamide, Acrylonitrile Butadiene Styrene (ABS), Polyurethane, Polycarbonate, Methacrylate, or glass.

7. A media conveying system comprising:
a media advancement roller to cause advancement of a media located between the media advancement roller and a sensing roller;
the sensing roller;
a housing that comprises a wall that enables the transfer of light therethrough;
a transducer within the housing to transform a force in the housing to an electric current, if the force exceeds a force threshold; and
a light source coupled to the transducer to emit light upon receiving the electric current.

8. The conveying system of claim 7, wherein the force is a compressing force caused by a load, the load to be generated by the sensing roller.

9. The conveying system of claim 7, wherein the system is a conveying system for a printing media device or a scanning media device.

10. The conveying system of claim 7, wherein the transducer is a piezoelectric element.

11. The conveying system of claim 7, wherein the light source is a Light-Emitting Diode (LED).

12. The conveying system of claim 7, wherein the housing is a wheel, a roller, or a sphere.

13. A system comprising:
a wheel to be coupled to a shaft, the shaft to receive a first load at a first end and a second load at a second end that cause a deflection in the shaft;
a transducer co-axially coupled to the shaft to transform the deflection to an electric current, if the deflection exceeds a deflection threshold; and
a light source coupled to the transducer to emit light upon receiving the electric current.

14. The system of claim 13, wherein the transducer is a piezoelectric element.

15. The system of claim 13, wherein the first load and the second load are caused by a weight of a machine.
